(19) United States
(12) Patent Application Publication
(10) Pub. No.: US 2025/0299971 A1
(43) Pub. Date: Sep. 25, 2025

(54) METHOD FOR MANUFACTURING WIRING SUBSTRATE

(71) Applicant: IBIDEN CO., LTD., Ogaki (JP)

(72) Inventors: Nobuhisa KURODA, Ibi-gun (JP); Toshihide MAKINO, Ibi-gun (JP)

(73) Assignee: IBIDEN CO., LTD., OgakI (JP)

(21) Appl. No.: 19/081,773

(22) Filed: Mar. 17, 2025

(30) Foreign Application Priority Data
Mar. 21, 2024 (JP) 2024-045522

(51) Int. Cl. H01L 21/48; G03F 7/00

(52) U.S. Cl. CPC H01L 21/4846; G03F 7/0035; G03F 7/70383

(57) ABSTRACT

A method for manufacturing a wiring substrate includes preparing two support substrates having one or more product areas, forming a first build-up part including first conductor and insulating layers across the one or more product areas on a first surface of each support substrate, positioning the substrates such that second surfaces of the substrates face each other, and forming a second build-up part including second conductor and insulating layers on each first build-up part. The minimum wiring width and the minimum inter-wiring distance of wirings in the first conductor layers are smaller than those of wirings in the second conductor layers. The forming the first build-up part includes forming a first resist layer having a first resist pattern and forming a conductor pattern according to the first resist pattern for each first conductor layer. The forming the first resist layer includes exposing the first resist layer by direct imaging exposure.

### CROSS-REFERENCE TO RELATED APPLICATIONS

The present application is based upon and claims the benefit of priority to Japanese Patent Application No. 2024-045522, filed Mar. 21, 2024, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2020-4926 describes a method for manufacturing a wiring substrate. The entire contents of this publication are incorporated herein by reference.

### SUMMARY OF THE INVENTION

According to one aspect of the present invention, a method for manufacturing a wiring substrate includes preparing two support substrates each having one or more product areas, forming a first build-up part including first conductor layers and first insulating layers across the one or more product areas on a first surface of each of the support substrates, positioning the two support substrates such that second surfaces of the support substrates face each other in a thickness direction of each of the support substrates and that the second surface of each of the support substrates is on the opposite side with respect to the first surface of a respective one of the support substrates, and forming a second build-up part including second conductor layers and second insulating layers on each of the first build-up parts on the opposite side with respect to the respective one of the support substrates such that the minimum wiring width and the minimum inter-wiring distance of wirings in the first conductor layers are smaller than the minimum wiring width and the minimum inter-wiring distance of wirings in the second conductor layers, respectively. The forming the first build-up part includes forming a first resist layer having a first resist pattern and forming a conductor pattern according to the first resist pattern for each of the first conductor layers, and the forming the first resist layer having the first resist pattern includes exposing the first resist layer by direct imaging exposure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a manufacturing method according to an embodiment of the present invention;

FIG. 2A illustrates an example of a manufacturing method according to an embodiment of the present invention;

FIG. 2B illustrates an example of a manufacturing method according to an embodiment of the present invention;

FIG. 2C illustrates an example of a manufacturing method according to an embodiment of the present invention;

FIG. 2D illustrates an example of a manufacturing method according to an embodiment of the present invention;

FIG. 2E illustrates an example of a manufacturing method according to an embodiment of the present invention;

FIG. 2F illustrates an example of a manufacturing method according to an embodiment of the present invention;

FIG. 2G illustrates an example of a manufacturing method according to an embodiment of the present invention;

FIG. 2H illustrates an example of a manufacturing method according to an embodiment of the present invention;

FIG. 2I illustrates an example of a manufacturing method according to an embodiment of the present invention;

FIG. 2J illustrates an example of a manufacturing method according to an embodiment of the present invention;

FIG. 2K illustrates an example of a manufacturing method according to an embodiment of the present invention;

FIG. 2L illustrates an example of a manufacturing method according to an embodiment of the present invention;

FIG. 2M illustrates an example of a manufacturing method according to an embodiment of the present invention;

FIG. 2N illustrates an example of a manufacturing method according to an embodiment of the present invention;

FIG. 2O illustrates an example of a manufacturing method according to an embodiment of the present invention;

FIG. 2P illustrates an example of a manufacturing method according to an embodiment of the present invention;

FIG. 2Q illustrates a manufacturing method according to an embodiment of the present invention;

FIG. 2R illustrates an example of a manufacturing method according to an embodiment of the present invention;

FIG. 2S illustrates an example of a manufacturing method according to an embodiment of the present invention; and

FIG. 2T illustrates an example of a manufacturing method according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

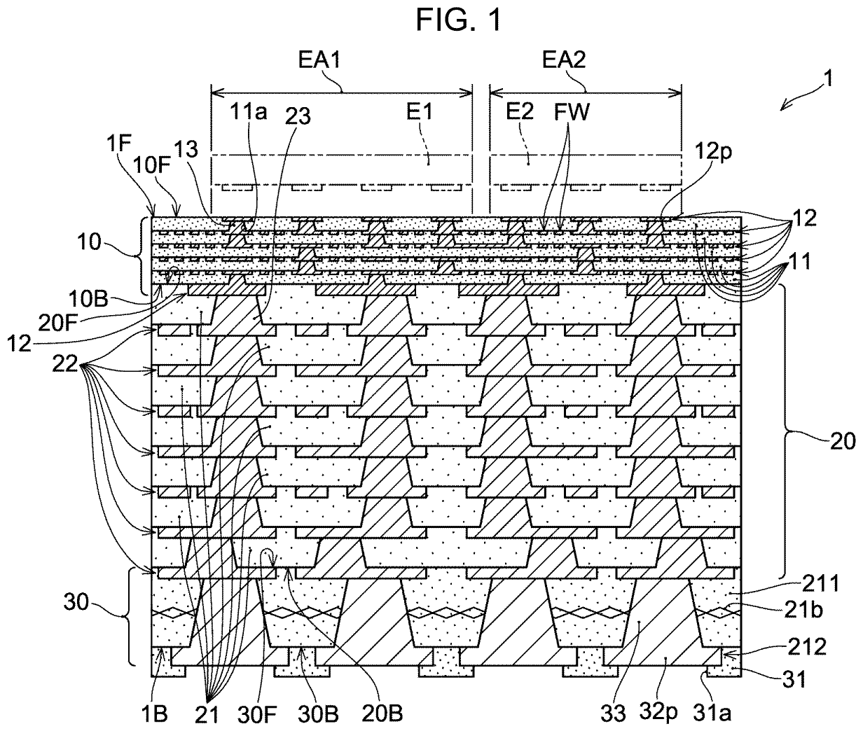

A wiring substrate manufactured using a method for manufacturing a wiring substrate according to an embodiment is described with reference to the drawings. FIG. 1 is a cross-sectional view illustrating a wiring substrate 1, which is an example of a wiring substrate manufactured using the manufacturing method of the embodiment. A laminated structure, as well as the number of conductor layers and insulating layers, of a wiring substrate to be manufactured are not limited to the laminated structure of the wiring substrate 1 of FIG. 1, and the number of conductor layers and insulating layers included in the wiring substrate 1.

The wiring substrate 1 has a laminated structure that includes a first build-up part 10 and a second build-up part 20, which are each formed of alternately laminated multiple conductor layers and multiple insulating layers. As illustrated in FIG. 1, the wiring substrate 1 may further include a third build-up part 30, which is formed of an insulating layer and a conductor layer laminated thereon, on the second build-up part 20 on an opposite side with respect to the first build-up part 10 side. The wiring substrate 1 has two surfaces (a first surface (1F) and a second surface (1B) on an opposite side with respect to the first surface (1F)) orthogonal to a thickness direction thereof. As illustrated in FIG. 1, a surface (first surface (10F)) of the first build-up part 10 forms the first surface (1F). When the wiring substrate 1 includes the third build-up part 30, the second surface (1B) can be formed by a surface (second surface (30B)) of the third build-up part 30. When the third build-up part 30 is not formed, and the wiring substrate is formed of the first build-up part 10 and the second build-up part 20, the second surface (1B) can be formed by a surface (second surface (20B)) of the second build-up part 20. The wiring substrate 1 is formed as a coreless wiring substrate that does not include a core layer.

The first build-up part 10 includes relatively fine wirings, and can have relatively dense circuit wirings. In the example of FIG. 1, the first build-up part 10 includes alternately laminated insulating layers (first insulating layers) 11 and conductor layers (first conductor layers) 12. Conductor layers 12 facing each other with one first insulating layer 11 in between are connected by via conductors (first via conductors) 13. The first conductor layers 12 are each patterned to have predetermined conductor patterns. The first surface (10F) of the first build-up part 10 is formed of a surface (upper surface) of a first conductor layer 12 and a surface (upper surface) of a first insulating layer 11 exposed from the patterns of the conductor layer 12. In the illustrated example, the conductor layer 12 forming the first surface (10F) is formed to have patterns including multiple conductor pads (12p).

In the description of the wiring substrate 1 illustrated in FIG. 1, the first surface (10F) side of the first build-up part 10, that is, the first surface (1F) side of the wiring substrate 1 is referred to as “upper” or an “upper side,” and the second surface (1B) side of the wiring substrate 1 is referred to as “lower” or a “lower side.” Further, for each of the structural elements, a surface facing the first surface (1F) side of the wiring substrate 1 is also referred to as an “upper surface,” and a surface facing the second surface (1B) side of the wiring substrate 1 is also referred to as a “lower surface.”

The conductor pads (12p) form a component mounting surface of the wiring substrate 1, which is an uppermost surface of the first build-up part 10, that is, an outermost surface of the wiring substrate 1, and on which external electronic components can be mounted. The component mounting surface of the wiring substrate 1 may have multiple component mounting regions. For example, as illustrated in the example of FIG. 1, two component mounting regions (EA1, EA2) may be formed corresponding to regions where electronic components (E1, E2) are to be mounted.

In mounting external electronic components to the wiring substrate 1 in the illustrated example, upper surfaces of the conductor pads (12p) can be electrically and mechanically connected to the external electronic components, for example, via a conductive bonding material such as solder (not illustrated in the drawings) interposed between the conductor pads (12p) and connection pads of the external electronic components. In this case, for example, a plating layer (not illustrated in the drawings) including a nickel layer and a tin layer may be formed in advance on the upper surfaces of the conductor pads (12p).

When the multiple component mounting regions are formed, conductor patterns may be formed in the conductor layers 12 in the first build-up part 10 such that conductor pads (12p) positioned in adjacent component mounting regions can be electrically connected to each other. In using the wiring substrate 1, multiple electronic components to be mounted are electrically connected to each other via the first build-up part 10 in short paths. Examples of the electronic components (E1, E2) that can be mounted on the wiring substrate 1 include electronic components such as active components such as semiconductor integrated circuit devices and transistors.

In the example of FIG. 1, the second surface (10B) of the first build-up part 10 on an opposite side with respect to the first surface (10F) is formed by a surface (lower surface) of an insulating layer 11 and a surface (including lower and side surfaces) of a conductor layer 12. The first build-up part 10 is laminated such that the second surface (10B) faces a first surface (20F) of the second build-up part 20 on an opposite side with respect to the second surface (20B).

The insulating layers 11 of the first build-up part 10 can be formed using an insulating resin such as an epoxy resin or a phenol resin. The insulating layers 11 may contain one of a fluorine resin, a liquid crystal polymer (LCP), a fluoroethylene resin (PTFE), a polyester resin (PE), and a modified polyimide resin (MPI). Examples of a conductor forming the conductor layers 12 and the via conductors 13 include copper, nickel, and the like, and copper is preferably used. In FIG. 1, for ease of viewing, the conductor layers 12 and the via conductors 13 are each illustrated as having a single-layer structure. However, the conductor layers 12 and the via conductors 13 can each have a multilayer structure. For example, the conductor layers 12 and the via conductors 13 can each have a two-layer structure including a metal film layer (preferably a sputtering film layer or an electroless plating film layer) and a plating film layer (preferably an electrolytic plating film layer).

Each via conductor 13 penetrating an insulating layer 11 in the thickness direction is formed by filling a through hole (11a) penetrating the insulating layer 11 with a conductor. In the example of FIG. 1, each via conductor 13 is integrally formed with a conductor layer 12 provided on a lower side thereof. Therefore, the via conductor 13 and the conductor layer 12 can be formed by the same metal film layer and plating film layer. The conductor layers 12 are respectively formed on the lower surfaces of the insulating layers 11. For example, the through holes (11a) are formed such that an aspect ratio of each via conductor 13 ((height from the upper surface of the lower conductor layer 12 to the lower surface of the upper conductor layer, the lower and upper conductor layers being connected by the via conductor 13)/(diameter of the via conductor 13 at the upper surface of the lower conductor layer 12)) is about 0.5 or more and about 1.0 or less. A via diameter of each via conductor 13 (a diameter of the via conductor 13 at the upper surface of the lower conductor layer 12 to which the via conductor 13 is connected) is about 10 μm. Although the term “diameter” is used, a planar shape of each of the via conductors 13 is not necessarily limited to a circular shape. The term “diameter” means a longest distance between two points on an outer circumference in a horizontal cross section of each of the via conductors 13.

The conductor layers 12 of the wiring substrate 1 may have fine wirings (FW), which are high-density wirings with relatively small wiring widths and inter-wiring distances (wiring intervals). The fine wirings (FW) can have smallest wiring width and inter-wiring distance among wirings that constitute the wiring substrate 1.

In the illustrated example, among the multiple conductor layers 12 included in the first build-up part 10, four conductor layers 12 have the fine wirings (FW), which are high-density wirings. In the first build-up part 10, any number of conductor layers 12 may include fine wirings (FW). The number of the conductor layers 12 having the fine wirings (FW) in the first build-up part 10 is not limited.

The fine wirings (FW) included in the first build-up part 10 have smaller wiring widths and inter-wiring distances than wiring widths and inter-wiring distances of wirings included in conductor layers (second conductor layers) 22 in the second build-up part 20 to be described later. Specifically, for example, the fine wirings (FW) have a minimum wiring width of 2 μm or less, and a minimum inter-wiring distance of 2 μm or less. Since the first build-up part 10 has the fine wirings (FW), it may be possible to provide wirings with more appropriate characteristics corresponding to electrical signals that can be transmitted via the wirings in the first build-up part 10. From a similar point of view, the fine wirings (FW) that can be included in the first conductor layers 12 each have an aspect ratio of, for example, 2.0 or more and 4.0 or less.

When the conductor layers 12 are formed to include the fine wirings (FW) as described above, it may be preferable that the via conductors 13 connecting opposing conductor layers 12 via an insulating layer 11 are also formed at a fine pitch. The through holes (11a) for the via conductors 13 with small diameters can be formed in the insulating layers 11. Therefore, although the insulating layers 11 can contain inorganic fillers such as fine particles of silica (SiO₂), alumina, mullite, or the like, in order to facilitate the formation of the through holes (11a) with small diameters, it may be preferred that the insulating layers 11 do not contain inorganic fillers.

In the first build-up part 10 including the conductor layers 12 including the fine wirings (FW), the insulating layers 11 each have a thickness of, for example, about 7.5 μm to 10 μm. Further, in this case, the insulating layers 11 preferably do not each contain a core material (reinforcing material) formed of a glass fiber, an aramid fiber, or the like.

The conductor layers 12 each have a thickness of 7 μm or less.

As illustrated in FIG. 1, the first build-up part 10 is laminated on the second build-up part 20. That is, the second surface (10B) of the first build-up part 10 faces the first surface (20F) of the second build-up part 20. Similar to the first build-up part 10, the second build-up part 20 includes alternately laminated insulating layers (second insulating layers) 21 and conductor layers (second conductor layers) 22. In each insulating layer 21, via conductors 23 are formed, which penetrate the insulating layer and connect conductor layers that oppose each other via the insulating layer. The conductor layers 22 are each patterned to have predetermined conductor patterns. As illustrated in FIG. 1, similar to the first build-up part 10, the second build-up part 20 does not include a core layer.

As illustrated in FIG. 1, the second surface (20B) of the second build-up part 20, which is formed of a lower surface of a lowermost insulating layer 21 and lower and side surfaces of a lowermost conductor layer 22 in the second build-up part 20, faces a first surface (30F) of the third build-up part 30. The third build-up part 30 includes an insulating layer 211 and a conductor layer 212 formed on a lower surface of the insulating layer 211. The insulating layer 211 covers the lower surfaces of the lowermost conductor layer 22 of the second build-up part 20 and the lowermost insulating layer 21 of the second build-up part 20 that is not covered by the conductor layer 22. In the insulating layer 211, via conductors 33 that penetrate the insulating layer 211 and connect the conductor layer 212 and the conductor layer 22 of the second build-up part 20 are formed.

The insulating layers 21 of the second build-up part 20 can be formed using the same insulating resin as the insulating layers 11. The insulating layers 21 may each contain a core material (reinforcing material) formed of a glass fiber or an aramid fiber. The insulating layer 211 of the third build-up part 30 contains a core material (21b) formed of a glass fiber. The insulating layers (21, 211) can each further contain an inorganic filler (not illustrated) formed of fine particles of silica (SiO₂), alumina, mullite, or the like. Similar to the conductor layers 12 and the via conductors 13, the conductor layers 22 of the second build-up part 20 and the conductor layer 212 of the third build-up part 30, as well as the via conductors (23, 33), can be formed using any metal such as copper or nickel.

As described above, wiring widths and inter-wiring distances of wirings included in the conductor layers 22 of the second build-up part 20 and the conductor layer 212 of the third build-up part 30 are larger than the wiring widths and inter-wiring distances of the wirings included in the conductor layers 12 of the first build-up part 10. The conductor layers 22 are formed thicker than the conductor layers 12, and each have a thickness of, for example, 10 μm or more. The conductor layers 22 of the second build-up part 20 do not include wiring patterns that can be formed at a fine pitch about the same as that of the fine wirings (FW) of the first build-up part 10. For example, the wirings included in the conductor layers 22 have a minimum wiring width of about 4 μm and a minimum inter-wiring distance of about 6 μm. A via diameter of each via conductor 23 (a diameter of the via conductor 23 at the upper surface of the lower conductor layer 22 to which the via conductor 23 is connected) is about 50 μm.

The insulating layer 211 and conductor layer 212 in the third build-up part 30 are both formed thicker than the insulating layers 21 and conductor layers 22 in the second build-up part 20. For example, the insulating layer 211 has a thickness of 100 μm or more and 200 μm or less. Further, the conductor layer 212 has a thickness of about 20 μm. A via diameter of each of the via conductors 33 formed in the insulating layer 211 (a diameter of each of the via conductors 33 on the upper surface of the conductor layer 212) is about 100 μm.

Similar to the conductor layers 12 and the via conductors 13, the conductor layers (22, 212) and the via conductors (23, 33) may be formed to each have a multilayer structure, for example, can each have a two-layer structure including a metal film layer and a plating film layer. The second build-up part 20 and the third build-up part 30 do not include fine wiring patterns such as the fine wirings (FW) of the first build-up part 10. In such a case, of the two-layer structure of each of the conductor layers 22 and via conductors 23 and the conductor layer 212 and via conductors 33, the metal film layer can be an electroless plating film layer formed by an electroless plating film, in particular, an electroless copper plating film layer, and the plating film layer can be an electrolytic plating film layer formed by an electrolytic plating film, in particular, an electrolytic copper plating film layer.

In the example of FIG. 1, the wiring substrate 1 further includes a solder resist layer 31 formed on the surfaces of the insulating layer 211 and the conductor layer 212. The solder resist layer 31 is formed using, for example, a photosensitive polyimide resin or epoxy resin. Openings (31a) are formed in the solder resist layer 31, and conductor pads (32p) of the conductor layer 212 of the third build-up part 30 are exposed from the openings (31a).

The second surface (1B) of the wiring substrate 1 on an opposite side with respect to the component mounting surface of the wiring substrate 1 can be a connection surface that is to be connected to an external element such as an external wiring substrate (for example, a motherboard of any electrical device) when the wiring substrate 1 itself is mounted on the external element. The conductor pads (32p) can be connected to any substrate, electronic component, mechanism element, or the like. The wiring substrate 1 can have a rectangular shape with each side measuring 80 mm or more and 240 mm or less in a plan view. The term “plan view” means viewing an object along the thickness direction of the wiring substrate 1.

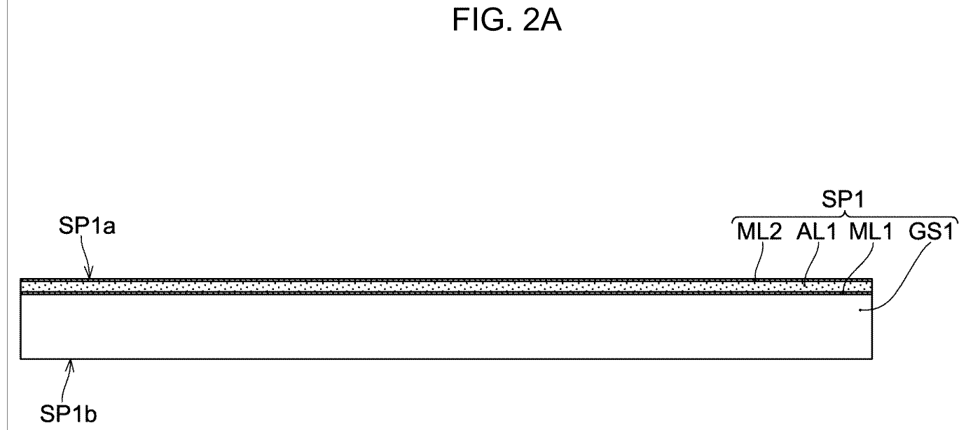

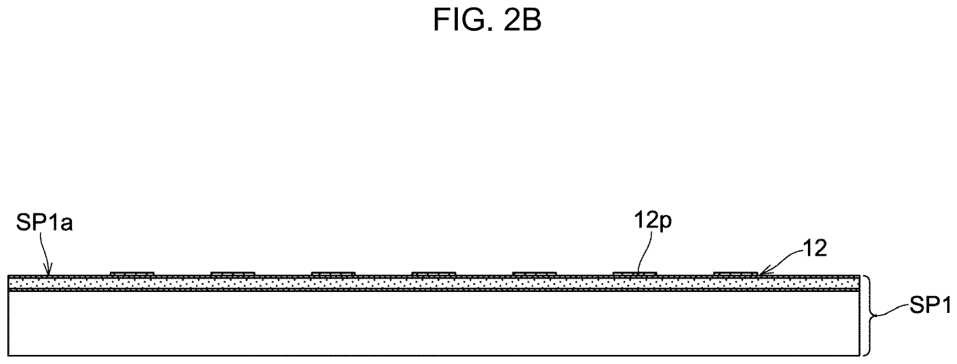

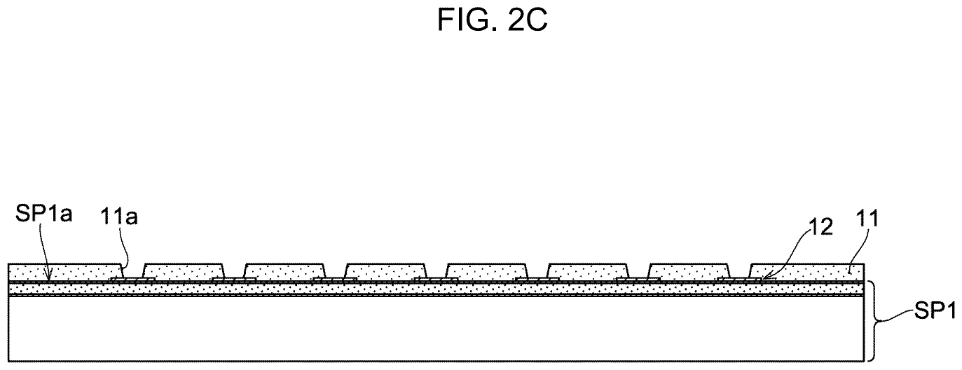

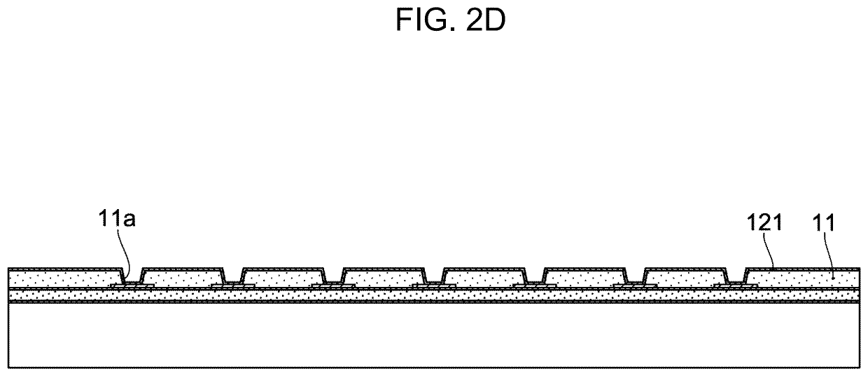

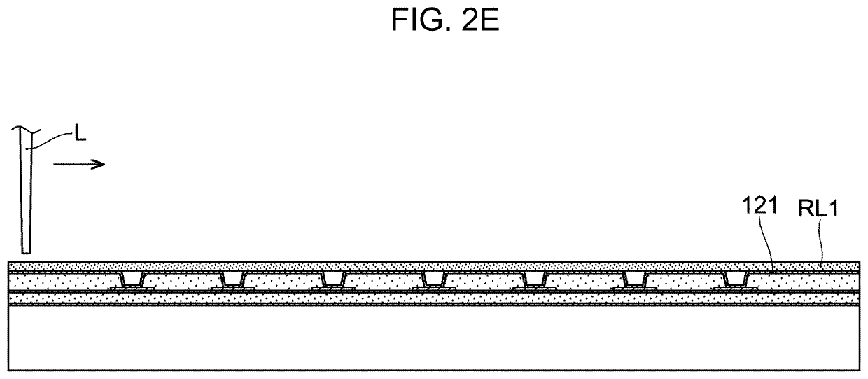

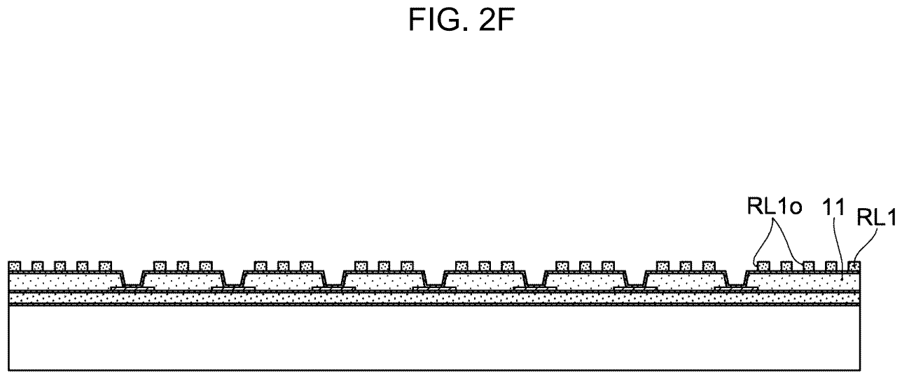

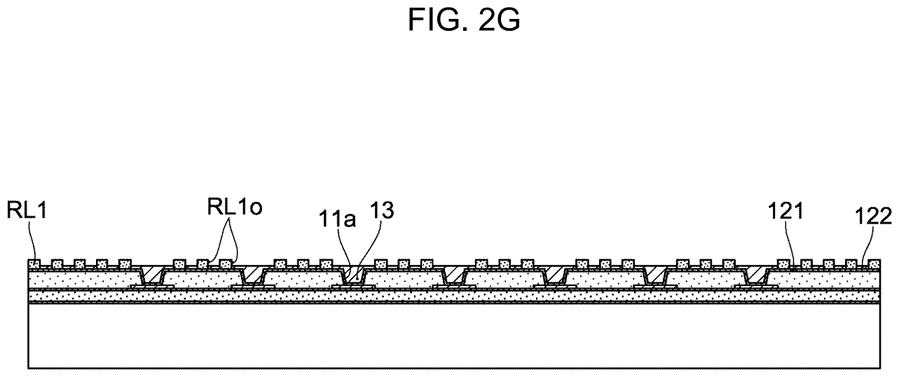

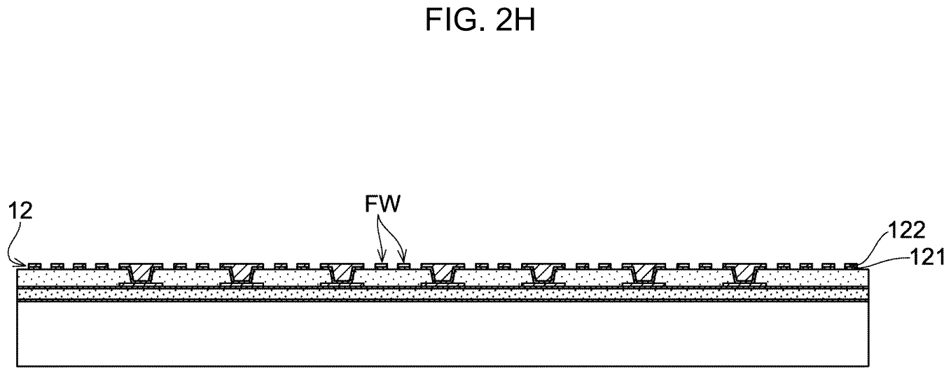

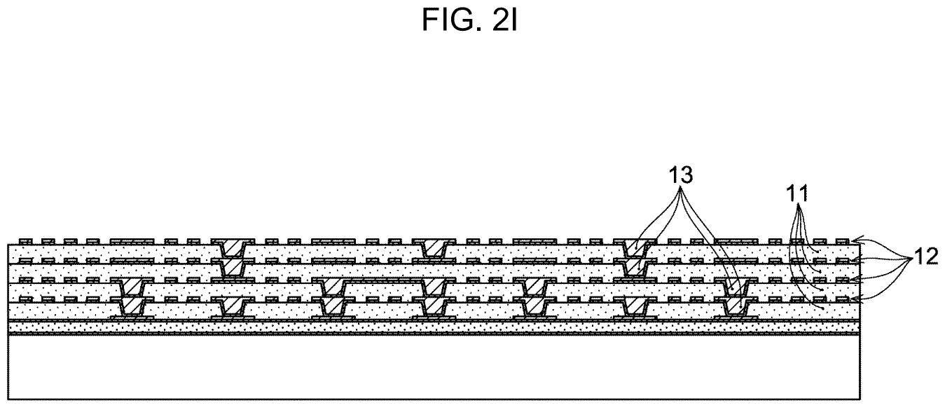

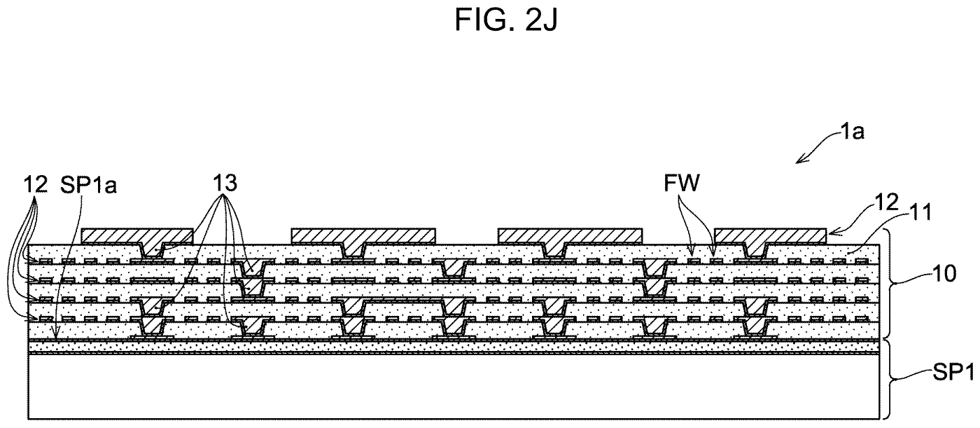

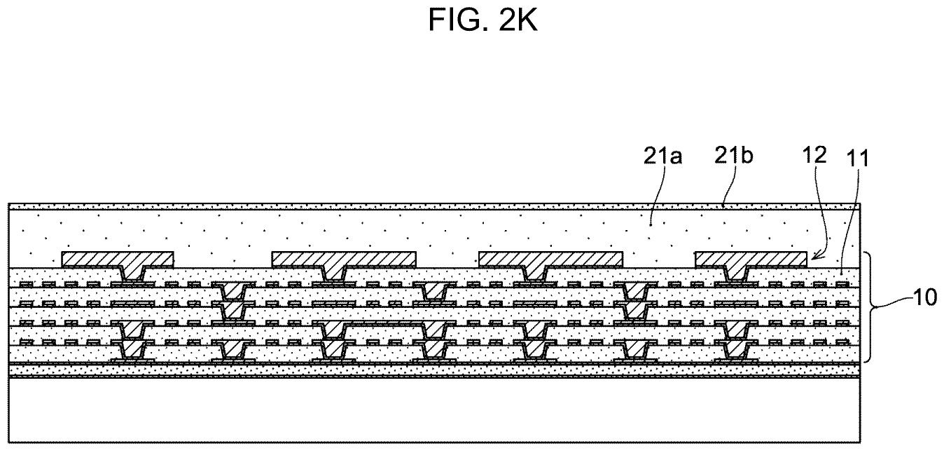

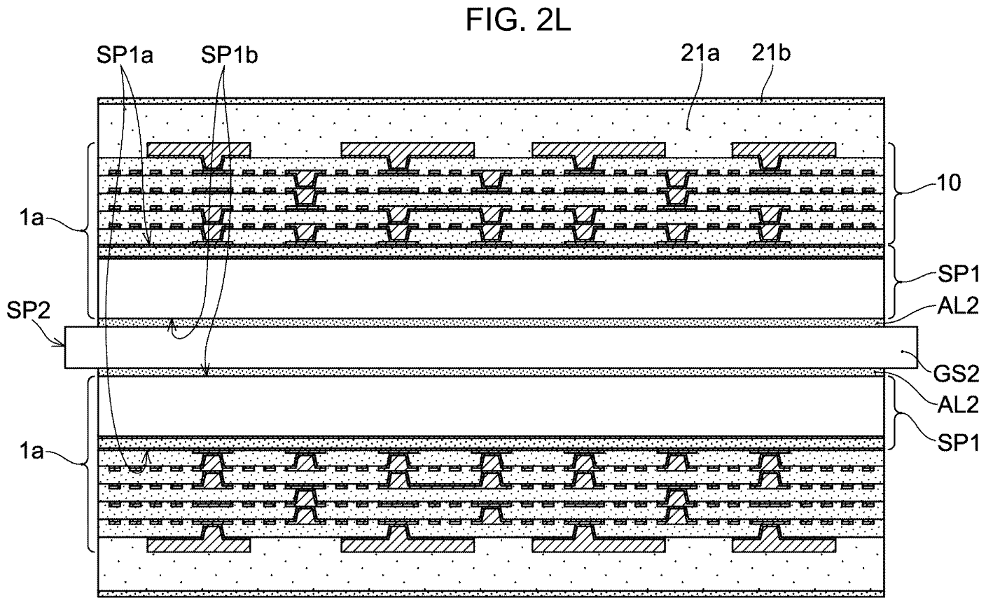

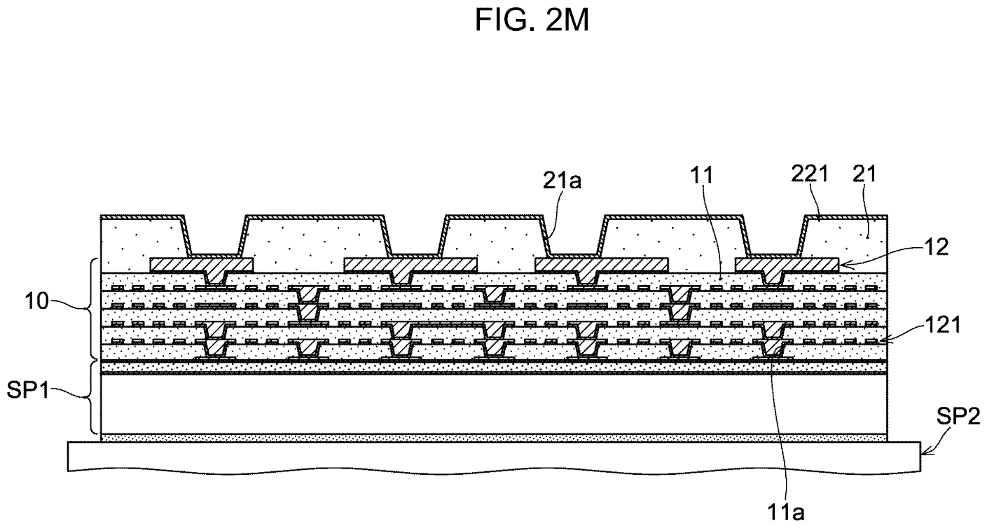

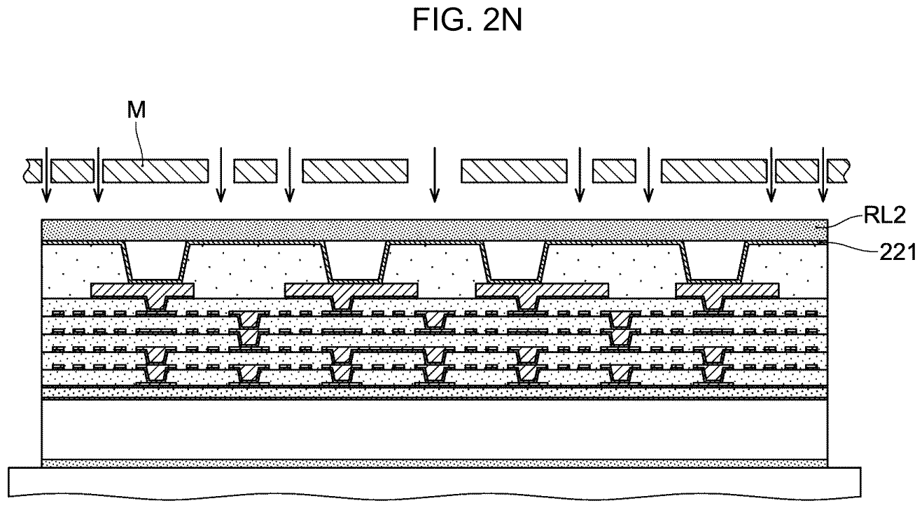

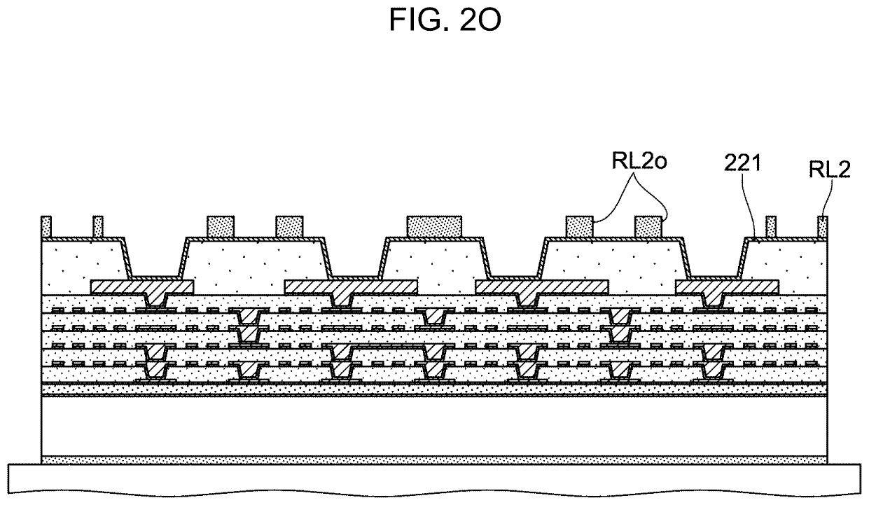

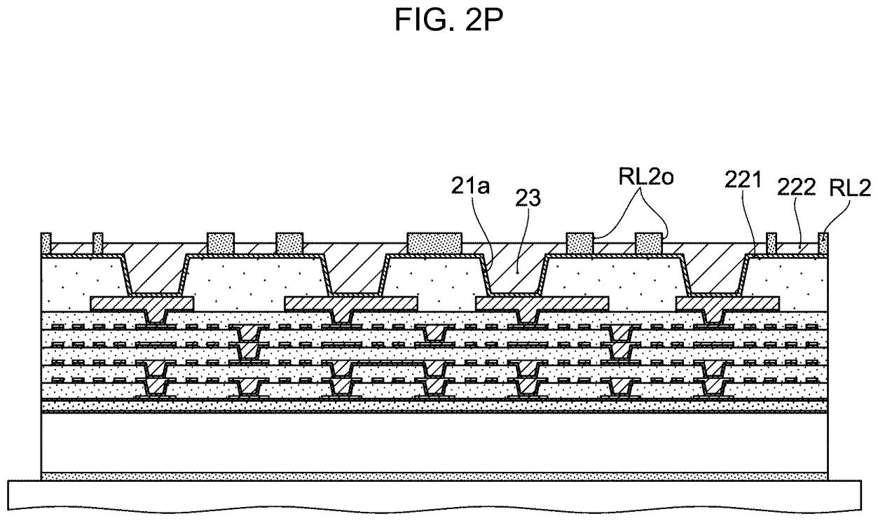

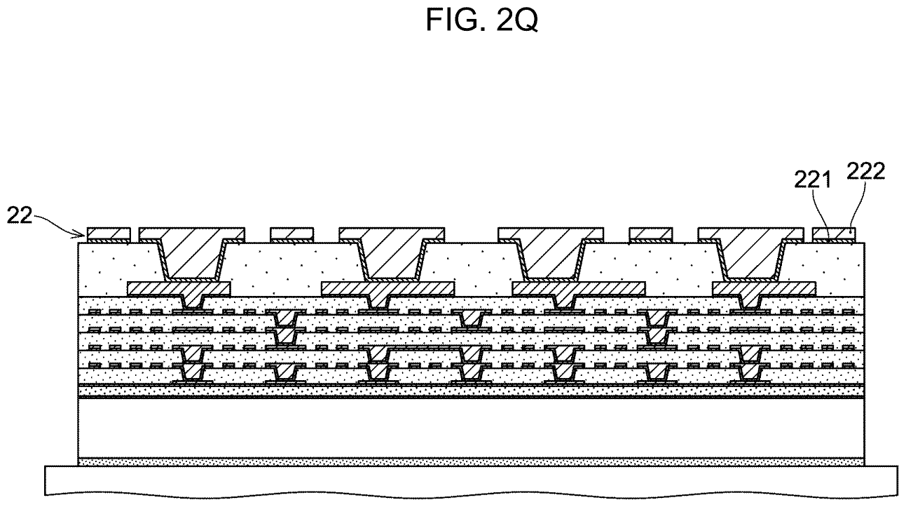

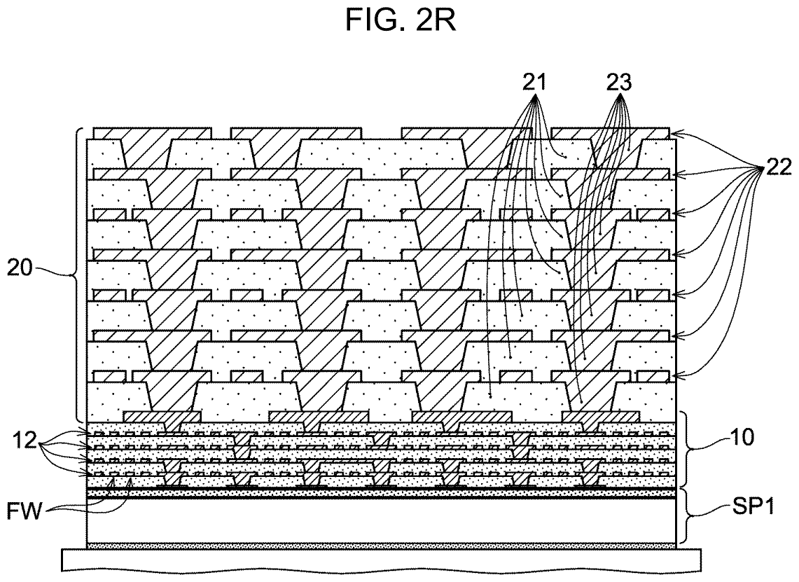

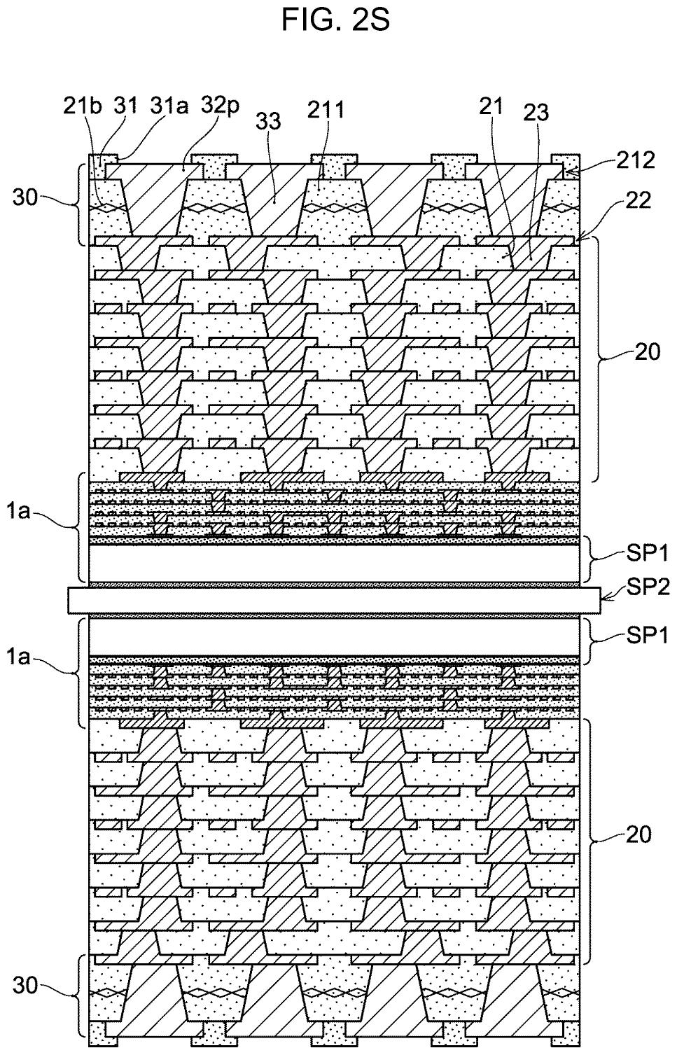

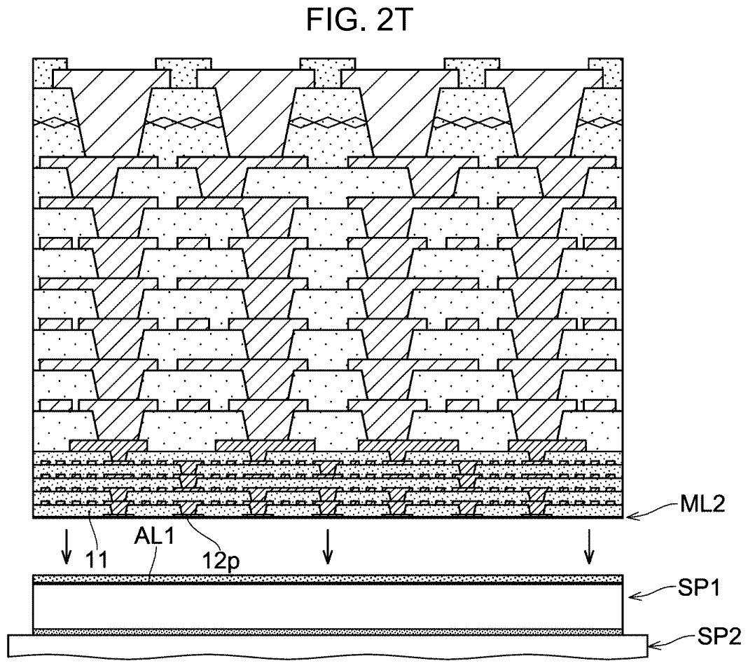

Subsequently, with reference to FIGS. 2A-2T, a method for manufacturing the wiring substrate of the embodiment is described using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. In the following description about the method for manufacturing the wiring structure 1, a side closer to a core material (GS1) constituting a first support substrate (SP1), on which the first build-up part 10 is formed, is referred to as “lower” or a “lower side,” and a side farther from the first support substrate (SP1) is referred to as “upper” or an “upper side.” Therefore, of each of the elements constituting the wiring structure 1, a surface facing the first support substrate (SP1) is referred to as a “lower surface,” and a surface facing an opposite side with respect to the first support substrate (SP1) is also referred to as an “upper surface.”

The method for manufacturing the wiring substrate of the embodiment includes: manufacturing a first build-up part 10 on a first surface (SP1a) among two main surfaces (surfaces orthogonal to a thickness direction), the first surface (SP1a) and a second surface (SP1b), of a first support substrate (SP1); positioning two manufactured first support substrates (SP1) (1a, see FIG. 2J), each having a first build-up part 10 laminated thereon, such that the second surfaces (SP1b) of the first support substrates (SP1) face each other in the thickness direction of the first support substrate (SP1); and laminating a second build-up part 20 on each of the first build-up parts 10. In the method for manufacturing the wiring substrate 1 to be described, a third build-up part 30 is further laminated on the second build-up part 20 (see FIG. 1). Two manufactured first support substrates (SP1) (1a, see FIG. 2J), each having a first build-up part 10 laminated thereon, may be attached to a second support substrate (SP2) such that the second surfaces (SP1b) of the first support substrates (SP1) face each other in the thickness direction with the second support substrate (SP2) interposed therebetween (see FIG. 2L).

First, as illustrated in FIG. 2A, the first support substrate (SP1) is prepared. In the method for manufacturing the wiring substrate of the embodiment, the first support substrate (SP1) to be used has good flatness on at least one of the two surfaces orthogonal to the thickness direction, that is, the surface (first surface (SP1a) in FIG. 2A) on which the first build-up part 10 is formed. The flatness of the first surface (SP1a) of the first support substrate (SP1) is, for example, within ±2.5 μm. Here, “flatness” is an indicator that allows smoothness (uniformity) of a flat surface to be expressed numerically, and is based on or conforms to JIS B 0621-1984. Therefore, a flatness of ±2.5 μm or less indicates that concave or convex deformation of the first support substrate (SP1) in the thickness direction relative to a reference virtual plane is within 2.5 μm on each side. The first support substrate (SP1) includes, for example, the core material (GS1), which is a glass substrate, a first metal film layer (ML1) laminated on at least one surface of the core material (GS1) (the surface on the first surface (SP1a) side of the first support substrate (SP1)), and a second metal film layer (ML2) laminated on the metal film layer (ML1) via an adhesive layer (AL1). The first and second metal film layers (ML1, ML2) are metal film layers formed by, for example, electroless plating or sputtering. In the illustration, the first and second metal film layers (ML1, ML2) are each depicted as a single layer, but they may each include multiple layers. For example, the first and second metal film layers (ML1, ML2) can each have a two-layer structure including a titanium layer and a copper layer. The adhesive layer (AL1) can contain, for example, an azobenzene-based polymer adhesive that can be attached or detached by irradiation with light. The first support substrate (SP1) can include, as the core material (GS1), a silicon substrate, a metal substrate, or a ceramic substrate in addition to a glass substrate.

In the following, in FIG. 2A as well as in FIGS. 2B to 2T, an example is illustrated in which one wiring substrate is formed on the first support substrate (SP1), and a method for manufacturing the wiring substrate is described. However, multiple wiring substrates can be formed on the first support substrate (SP1). Specifically, the surface of the first support substrate (SP1) has one or multiple continuous product areas, and a laminate (build-up part) including one wiring substrate in each product area is formed on the surface of the first support substrate (SP1). When the first support substrate (SP1) has multiple product areas, wiring substrates are manufactured by dividing the formed laminate for each product area.

Next, as illustrated in FIG. 2B, a conductor layer 12 having multiple conductor pads (12p) is formed on the first surface (SP1a) of the first support substrate (SP1). In forming the conductor layer 12 in contact with the first support substrate (SP1), for example, a plating resist is formed on the metal film layer (ML2), and openings corresponding to pattern formation regions of the conductor pads (12p) are formed in the plating resist, for example, using a photolithography technology. Next, a plating film layer is formed in the openings by electrolytic plating using the metal film layer (ML2) as a seed layer. After the formation of the plating film layer, the plating resist is removed, and the state illustrated in FIG. 2B is formed.

Next, as illustrated in FIG. 2C, an insulating layer 11 is laminated to cover upper and side surfaces of the conductor layer 12, as well as the first surface (SP1a) of the first support substrate (SP1) exposed from the conductor patterns of the conductor layer 12. As the insulating layer 11, for example, an insulating resin such as an epoxy resin or a phenol resin can be used. A fluorine resin, a liquid crystal polymer (LCP), a fluoroethylene resin (PTFE), a polyester resin (PE), or a modified polyimide resin (MPI) also may be used. The insulating layer 11 is formed by thermocompression bonding these resins molded into a film-like shape. Next, through holes (11a) are formed at formation positions of via conductors 13 (see FIG. 1) in the insulating layer 11, for example, by irradiation with CO₂ laser, excimer laser, or the like.

Although not illustrated, the formation of the through holes (11a) by irradiation with laser such as CO₂ laser can be performed by irradiating laser while protecting the upper surface of the insulating layer 11 by covering the upper surface with a protective film such as a polyethylene terephthalate (PET) film. The through holes (11a) penetrating the protective film and the insulating layer 11 are formed. Further, after the through holes (11a) are formed, a desmear treatment may be performed to prevent a decrease in adhesion or an increase in a resistance component or the like during the formation of the conductor layer 12 due to a processing-modified substance occurring at bottoms of the through holes (11a). The desmear treatment can preferably be a dry desmear treatment using a plasma gas. The desmear treatment may also be performed while protecting the surface of the insulating layer 11 in a state in which a protective film such as a polyethylene terephthalate (PET) film is formed on the surface of the insulating layer 11.

Next, as illustrated in FIG. 2D, a metal film layer 121 is formed on inner walls of the through holes (11a) and on the surface of the insulating layer 11 by electroless plating, sputtering, or the like. Preferably, the metal film layer 121 can be a sputtering film formed by sputtering. When a protective film is provided on the surface of the insulating layer 11 during the formation of the through holes (11a) and/or during the desmear treatment, the protective film can be peeled off before the formation of the metal film layer 121.

Next, as illustrated in FIG. 2E, for example, a dry film resist containing a photosensitive epoxy resin is adhered onto the metal film layer 121, and a resist layer (RL1) is formed in contact with an upper surface of the metal film layer 121. Subsequently, the resist layer (RL1) is subjected to exposure. In the method for manufacturing the wiring substrate of the embodiment, direct imaging exposure is preferably performed in the process of exposing the resist layer (RL1). In the direct imaging exposure, a photomask is not used, and irradiation light (L) is directly irradiated onto the resist layer (RL1). As a light source for the irradiation light (L), for example, a semiconductor laser with a wavelength of 350 nm to 410 nm or an ultra-high-pressure mercury lamp can be used. The irradiation light (L) is scanned according to drawing patterns corresponding to the conductor patterns of the first conductor layer 12 to be formed on the insulating layer 11 (see FIG. 2H). An exposure amount can be determined by the illuminance of the exposure light source and a scanning speed of the irradiation light (L).

Next, as illustrated in FIG. 2F, resist patterns corresponding to the conductor patterns (see FIG. 2H) of the first conductor layer 12 to be formed on the insulating layer 11 are formed in the first resist layer (RL1). Specifically, after the above-described process of exposing the resist layer (RL1) is completed, the resist layer (RL1) is developed to form openings (RL1o), using a developer including a sodium carbonate aqueous solution which can contain, for example, a surfactant, a defoaming agent, a small amount of an organic solvent for promoting development, and the like. When the wirings (FW) (see FIG. 2H) are included as the conductor patterns of the first conductor layer 12 to be formed on the insulating layer 11, the openings (RL1o) corresponding to the wirings (FW) are formed such that a minimum opening width is 2 μm or less and a minimum inter-opening distance is 2 μm or less. In the description of the method for manufacturing the wiring substrate, in the formation of the conductor layer 12 of the first build-up part 10, the resist layer exposed by the direct imaging exposure is also referred to as the first resist layer (RL1), and the resist patterns formed in the first resist layer (RL1) are also referred to as the first resist patterns.

Next, as illustrated in FIG. 2G, a plating film layer 122 is formed in the openings (RL10) of the first resist layer (RL1) by electrolytic plating using the metal film layer 121 as a power feeding layer. The via conductors 13 are formed by completely filling the through holes (11a) with an electrolytic plating film.

Next, the first resist layer (RL1) is removed using an alkaline peeling solution, and then a portion of the metal film layer 121 that is not covered by the plating film layer 122 is removed by etching. As a result, as illustrated in FIG. 2H, a conductor layer 12 having a two-layer structure including the metal film layer 121 and the plating film layer 122 and having the fine wirings (FW) is formed. The conductor layer 12 can be formed to have a thickness of, for example, 7 μm or less, and the wirings (FW) can be formed to have a minimum wiring width of 2 μm or less, a minimum inter-wiring distance of 2 μm or less, and an aspect ratio of, for example, 2.0 or more and 4.0 or less.

Next, as illustrated in FIG. 2I, using similar methods to the methods for forming the insulating layer 11, the conductor layer 12 and the via conductors 13 described above, on the conductor layer 12 and the insulating layer 11, a desired number of insulating layers 11 and conductor layers 12, and via conductors 13 penetrating the respective insulating layers, are formed.

Next, as illustrated in FIG. 2J, on the upper side of the conductor layer 12, the uppermost insulating layer 11 and conductor layer 12 among the insulating layers 11 and conductor layers 12 of the first build-up part 10 are formed. A first support substrate (SP1) (1a) is manufactured in which the first build-up part 10 is formed on the first surface (SP1a) of the first support substrate (SP1). By forming the first build-up part 10 on the first surface (SP1a) of the first support substrate (SP1) having good flatness, the conductor layers 12 in the first build-up part 10 can have high flatness. It is thought that a problem such as misalignment or insufficient adhesion is unlikely to occur during the formation of the via conductors 13 connected to the conductor layers 12. A first build-up part 10 with high connection reliability can be formed. This is thought particularly advantageous when the conductor layers 12 in the first build-up part 10 include the fine wirings (FW).

As described above, in the method for manufacturing the wiring substrate of the embodiment, the direct imaging exposure is preferably used to form the resist patterns of the first resist layer (RL1). As a result, it is thought that the yield in the manufacturing of the wiring substrate can be improved. Specifically, in an exposure method using a photomask, exposure is performed on a per-photomask basis, so a focal depth can also be adjusted only on a per-photomask basis. On the other hand, in the direct imaging exposure, there is no need to use a photomask, allowing the focal depth to be adjusted on a per-exposure beam basis. Therefore, when the direct imaging exposure is employed for the formation of the conductor layer 12, which can include the relatively fine wirings (FW), it is thought that the resolution of the resist patterns is superior compared to the case where exposure is performed using a photomask.

In the method for manufacturing the wiring substrate, each product area on the surface of the first support substrate (SP1) has a rectangular shape with each side measuring 80 mm or more and 240 mm or less in a plan view. Therefore, the laminate (build-up part) formed across one or multiple product areas of the first support substrate (SP1) has at least a rectangular shape with each side measuring 80 mm or more in a plan view. In this way, when a relatively large-sized laminate is manufactured, in exposure using a photomask that limits a range that can be exposed in one exposure, it may require repeated exposures across different areas, which can lead to an increase in the number of processes in the exposure process. In contrast, in the direct imaging exposure, the entire area of the wiring substrate is scanned with the irradiation light in one exposure, so an increase in the number of processes in the exposure process is suppressed, and therefore the yield in the manufacturing of the wiring substrate may be improved.

As illustrated, the uppermost conductor layer 12 does not include the wirings (FW), and in such a case, the conductor layer 12 may be formed using a method that includes the formation of resist patterns by exposure using a photomask for a resist layer. Also, the uppermost conductor layer 12 that does not include the wirings (FW) may also be formed using a method similar to that for the formation of the insulating layer 11 and the conductor layer 12 on the insulating layer 11 described above (the method that includes the direct imaging exposure for the resist layer).

In the method for manufacturing the wiring substrate of the embodiment, in the formation of the multiple conductor layers 12 constituting the first build-up part 10, it is sufficient when any of the conductor layers 12 is formed using the method that includes the direct imaging exposure for the resist layer. Therefore, for example, in the illustrated example, the lowermost conductor layer 12 in the first build-up part 10 (the conductor layer 12 in contact with the first support substrate (SP1)), which does not include the wirings (FW), also may be formed using a method that includes formation of resist patterns by exposure using a photomask for a resist layer, or may be formed using a method that includes the direct imaging exposure.

Subsequently, as illustrated in FIG. 2K, an insulating layer (21a) that forms the lowermost insulating layer 21 of the second build-up part 20 (see FIG. 2R) is laminated on the uppermost insulating layer 11 and conductor layer 12 of the first build-up part 10. The insulating layer (21a) is formed of an insulating resin similar to the insulating resin that forms the insulating layer 11. A film (21b) formed of a resin such as polyethylene terephthalate peelably bonded to the insulating layer (21a) is laminated on the insulating layer (21a) is

In the method for manufacturing the wiring substrate of the embodiment, next, the first support substrate (SP1) (1a), on which the first build-up part 10 with the insulating layer (21a) and film (21b) is laminated, is attached to a second support substrate (SP2). As illustrated in FIG. 2L, a first support substrate (SP1) (1a) with a first build-up part 10 laminated thereon is attached to each of two main surfaces (surfaces orthogonal to the thickness direction) of the second support substrate (SP2). The second support substrate (SP2) includes, for example, a core material (GS2), which is a glass substrate similar to the core material (GS1) of the first support substrate (SP1). Alternately, for the second support substrate (SP2), a copper clad laminate (CCL) or a double-sided copper-clad laminate, which includes an insulating layer and copper foil thermocompression bonded to both sides of the insulating layer, may be used. The main surfaces of the second support substrate (SP2) are respectively bonded to the second surfaces (SP1b) of the first support substrates (SP1). For example, the bonding can be performed via an adhesive layer (AL2) formed of any adhesive, such as an epoxy or acrylic resin. However, it is also possible that the two first support substrates (SP1) (1a), each having a first build-up part 10 laminated thereon, are bonded together using the same type of adhesive, with their respective second surfaces (SP1b) facing each other, without the second support substrate (SP2) interposed therebetween.

Next, the film (21b) is peeled off from the insulating layer (21a) on the main surfaces of the second support substrate (SP2). After that, the insulating layer (21a) is thermally cured, and as a result, as illustrated in FIG. 2M, the lowermost insulating layer 21 of the second build-up part 20 (see FIG. 2R) is formed on the uppermost insulating layer 11 and conductor layer 12 of the first build-up part 10. Subsequently, using similar methods to the formation of the through holes (11a) and the formation of the metal film layer 121 described with reference to FIGS. 2C and 2D, through holes (21a) are formed, and a metal film layer 221 is formed on the upper surface of the insulating layer 21 and inner surfaces of the through holes (21a).

In FIG. 2M, and FIGS. 2N-2R to be referenced below, the laminate formed on the surface on one side of the second support substrate (SP2) is illustrated, and illustration of the laminate that can be formed on the surface on the opposite side is omitted. However, on the surface on the opposite side of the second support substrate (SP2), laminates of a similar form and number may also be formed at the same time as the formation of a second build-up part or third build-up part formed on the illustrated surface.

Next, as FIG. 2N, a resist layer (RL2) is formed on the metal film layer 221. Subsequently, the resist layer (RL2) is subjected to exposure. In the process of exposing the resist layer (RL2), exposure using a photomask (M) can be performed. Further, it is also possible that direct imaging exposure is performed in the process of exposing the resist layer (RL2). In this case, compared to the direct imaging exposure performed in the process of exposing the resist layer (RL1), direct imaging exposure with a larger beam spot diameter and lower resolution of the formed resist patterns can be performed.

Next, as illustrated in FIG. 2O, similar to the development of the first resist layer (RL1) described above with reference to FIG. 2F, the resist layer (RL2) is developed using a developer to form resist patterns corresponding to the conductor patterns of the second conductor layer 22 (see FIG. 2Q). Specifically, openings (RL2o) corresponding to the conductor patterns of the second conductor layer 22 to be formed are formed. When wirings are included as the conductor patterns of the second conductor layer 22 to be formed on the insulating layer 21, the openings (RL2o) corresponding to the wirings can be formed to have a minimum opening width of about 4 μm and a minimum inter-opening distance of about 6 μm. The resist layer used in the formation of the conductor layer 22 is also referred to as the second resist layer (RL2), and the resist patterns formed in the second resist layer (RL2) are also referred to as the second resist patterns.

Subsequently, as illustrated in FIG. 2P, a plating film layer 222 is formed in the openings (RL2o) of the second resist layer (RL2) by electrolytic plating using the metal film layer 221 as a power feeding layer. The via conductors 23 are formed by completely filling the through holes (21a) with an electrolytic plating film.

Next, the second resist layer (RL2) is removed using a peeling solution, and then a portion of the metal film layer 221 that is not covered by the plating film layer 222 is removed by etching. As a result, as illustrated in FIG. 2Q, the second conductor layer 22 having a two-layer structure including the metal film layer 221 and the plating film layer 222 is formed. The second conductor layer 22 can be formed to have a thickness of, for example, 10 μm or more. The second conductor layer 22 can be formed to include wirings having a minimum wiring width of about 4 μm and a minimum inter-wiring distance of about 6 μm.

Next, as illustrated in FIG. 2R, the process of forming the insulating layer 21, the conductor layer 22, and the via conductors 23 described above is repeated to form a desired number of insulating layers 21 and conductor layers 22, as well as via conductors 23 that penetrate the respective insulating layers 21. The formation of the second build-up part 20 on the first build-up part 10 is completed. In the formation of the first build-up part 10 and the second build-up part 20, the minimum wiring width of the wirings (FW) in the first conductor layers 12 is smaller than the minimum wiring width of the wirings in the second conductor layers 22, and the minimum inter-wiring distance of the wirings (FW) in the first conductor layers 12 is smaller than the minimum inter-wiring distance of the wirings in the second conductor layers 22. In FIG. 2R and the following FIGS. 2S and 2T, the metal film layers (121, 221) and the plating film layers (122, 222) are not depicted, and the conductor layers (12, 22) are depicted as each having a single-layer structure, similar to that in FIG. 1.

As described above, in the method for manufacturing the wiring substrate 1, the second build-up part 20, which has the conductor layers 22 with relatively relaxed wiring rules compared to the first build-up part 10, is laminated on the first build-up part 10, following the lamination of the first build-up part 10 onto the first support substrate (SP1). Therefore, compared to a manufacturing method in which the first build-up part 10 and the second build-up part 20, formed as separate entities, are bonded via connecting members, the present method may enable manufacturing of the wiring substrate with fewer processes.

Next, as illustrated in FIG. 2S, on the uppermost insulating layer 21 and conductor layer 22 of the second build-up part 20, the insulating layer 211, the conductor layer 212, and the via conductors 33, which penetrate the insulating layer 211, of the third build-up part 30 are formed using methods similar to those used for forming the insulating layers 21, the conductor layers 22, and the via conductors 23. As an insulating resin forming the insulating layer 211, a prepreg containing an insulating resin such as an epoxy resin or a BT resin impregnated in a reinforcing material (core material) (21b) formed of a glass fiber is used. That is, as illustrated in FIG. 2S, on each of the two main surfaces of the second support substrate (SP2), a first support substrate (SP1) (1a) with a first build-up part 10 laminated thereon, a second build-up part 20, and a third build-up part 30 are formed in order from the second support substrate (SP2). Subsequently, the solder resist layer 31 is formed by forming a photosensitive epoxy resin or polyimide resin layer on the surfaces of the insulating layer 211 and the conductor layer 212. Then, using a photolithography technology, the openings (31a) that respectively define the conductor pads (32p) are formed.

Next, as illustrated in FIG. 2T, the first support substrate (SP1) can be removed from the laminate including the first build-up part 10, together with the second support substrate (SP2), from the adhesive layer (AL1). Although not illustrated in FIG. 2T, the removal of the first support substrate (SP1) can be performed for the first support substrates (SP1) on both sides of the second support substrate (SP2). The lower surface of the second metal film layer (ML2) below the conductor pads (12p) is exposed. In the removal of the first support substrate (SP1), for example, after the adhesive layer (AL1) is irradiated with laser and is softened, the second metal film layer (ML2) of the first support substrate (SP1) is peeled off. Subsequently, the second metal film layer (ML2) is removed by etching, exposing the lower surfaces of the conductor pads (12p) and the lower surface of the insulating layer 11. A laminate that can include multiple wiring substrates is divided by product areas, forming individual independent wiring substrates. The wiring substrate 1 illustrated in FIG. 1 is completed.

In the method for manufacturing the wiring substrate of the embodiment, first, a high-quality first build-up part 10 with high flatness is formed on a first support substrate (SP1). Then, two first support substrates (SP1) (1a), each having a first build-up part 10 laminated thereof, are positioned such that their respective second surfaces (SP1b) face each other. After that, a second build-up part 20 and a third build-up part 30 are sequentially laminated onto each of the first build-up parts 10. It is thought that a yield of wiring substrate manufacturing is improved, enabling efficient manufacture of high-quality wiring substrate 1 with a high yield.

The method for manufacturing the wiring substrate of the embodiment is not limited to the method described with reference to FIGS. 2A-2T, and the conditions, processing order and the like of the method can be modified as needed. Further, it is also possible that a specific process is omitted or another process is added. For example, a solder resist layer having openings exposing the conductor pads (12p) may be formed on the conductor pads (12p) and insulating layer 11, which are exposed after the second metal film layer (ML2) is removed by etching. Further, conductor bumps connecting to the conductor pads (12p) may be formed in the openings provided in the solder resist layer. A plating layer including a nickel layer and a tin layer may be formed on the surfaces of the conductor bumps.

Japanese Patent Application Laid-Open Publication No. 2020-4926 describes a method for manufacturing a wiring substrate that includes a second wiring substrate and a first wiring substrate. The first wiring substrate is formed by laminating an insulating resin and a wiring layer onto a support substrate. The second wiring substrate is manufactured separately from the first wiring substrate. After the first wiring substrate is bonded to the second wiring substrate, the support substrate is peeled off.

In the method for manufacturing the wiring substrate described in Japanese Patent Application Laid-Open Publication No. 2020-4926, the first wiring substrate and the second wiring substrate, which include relatively fine wiring layers, are bonded via terminals protruding from respective surfaces thereof, and an insulating resin is filled between the first wiring substrate and the second wiring substrate. It is thought that this may lead to a lower yield in the manufacturing of the wiring substrate.

A method for manufacturing a wiring substrate according to an embodiment of the present invention includes: preparing two first support substrates, each having a first surface and a second surface on an opposite side with respect to the first surface, and each having one or multiple product areas; forming a first build-up part including first conductor layers and first insulating layers by alternately laminating the first conductor layers and the first insulating layers across the one or multiple product areas on the first surface of each of the first support substrates; and positioning the second surfaces of the two first support substrates to face each other in a thickness direction of each of the first support substrates, and forming a second build-up part by alternately laminating second conductor layers and second insulating layers on each of the first build-up parts on an opposite side with respect to the respective first support substrates. The laminating of the first conductor layers includes forming a first resist layer having first resist patterns and forming conductor patterns according to the first resist patterns. The forming of the first resist layer having the first resist patterns includes exposing the first resist layer by direct imaging exposure. The first conductor layers and the second conductor layers are formed such that a minimum wiring width and a minimum inter-wiring distance of wirings in the first conductor layers are respectively smaller than a minimum wiring width and a minimum inter-wiring distance of wirings in the second conductor layers.

According to an embodiment of the present invention, a wiring substrate including multiple conductor layers with different wiring densities can be manufactured with a high yield and efficiency.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
preparing two support substrates each having at least one product area;
forming a first build-up part comprising a plurality of first conductor layers and a plurality of first insulating layers across the at least one product area on a first surface of each of the support substrates;
positioning the two support substrates such that second surfaces of the support substrates face each other in a thickness direction of each of the support substrates and that the second surface of each of the support substrates is on an opposite side with respect to the first surface of a respective one of the support substrates; and
forming a second build-up part comprising a plurality of second conductor layers and a plurality of second insulating layers on each of the first build-up parts on an opposite side with respect to the respective one of the support substrates such that a minimum wiring width and a minimum inter-wiring distance of wirings in the first conductor layers are smaller than a minimum wiring width and a minimum inter-wiring distance of wirings in the second conductor layers, respectively,
wherein the forming the first build-up part includes forming a first resist layer having a first resist pattern and forming a conductor pattern according to the first resist pattern for each of the first conductor layers, and the forming the first resist layer having the first resist pattern includes exposing the first resist layer by direct imaging exposure.

2. The method for manufacturing a wiring substrate according to claim 1, wherein the positioning the two support substrates to face each other includes bonding the two support substrates to a second support substrate such that the second support substrate is sandwiched between the two support substrates.

3. The method for manufacturing a wiring substrate according to claim 2, further comprising:
removing the support substrates together with the second support substrate from two structures each comprising the first and second build-up parts after the forming of the second build-up part.

4. The method for manufacturing a wiring substrate according to claim 1, wherein the forming the second build-up part includes forming a second resist layer having a second resist pattern and forming a second conductor pattern according to the second resist pattern for each of the second conductor layers, and the forming of the second resist layer having the second resist pattern includes exposing the second resist layer using a photomask.

5. The method for manufacturing a wiring substrate according to claim 1, wherein the at least one product area in each of the support substrates has a rectangular shape with each side in a range of 80 mm to 240 mm.

6. The method for manufacturing a wiring substrate according to claim 1, wherein the first surface of each of the support substrates has a flatness of ±2.5 μm or less.

7. The method for manufacturing a wiring substrate according to claim 6, wherein each of the support substrates is one of a glass substrate, a silicon substrate, a metal substrate, and a ceramic substrate.

8. The method for manufacturing a wiring substrate according to claim 1, wherein the forming the first build-up part includes forming the first conductor layers each having the conductor pattern such that wirings in the conductor pattern have a minimum width of 2 μm or less and a minimum inter-wiring distance of 2 μm or less.

9. The method for manufacturing a wiring substrate according to claim 1, wherein the first build-up part is formed such that each of the first conductor layers has a thickness of 7 μm or less, and the second build-up part is formed such that each of the second conductor layers has a thickness of 10 μm or more.

10. The method for manufacturing a wiring substrate according to claim 1, wherein the first build-up part is formed such that the first conductor layers include wirings each having an aspect ratio of 2.0 or more and 4.0 or less.

11. The method for manufacturing a wiring substrate according to claim 1, further comprising:
forming a third build-up part comprising a plurality of third insulating layers and a plurality of third conductor layers on the second build-up part on an opposite side with respect to the first build-up part.

12. The method for manufacturing a wiring substrate according to claim 1, wherein the forming the second build-up part includes forming one of the second insulating layers on the first build-up part on a respective one of the support substrates before positioning the second surfaces of the support substrates to face each other.

13. The method for manufacturing a wiring substrate according to claim 1, wherein the forming the first build-up part includes alternately laminating the first conductor layers and the first insulating layers, and the forming the second build-up part includes alternately laminating the second conductor layers and the second insulating layers.

14. The method for manufacturing a wiring substrate according to claim 11, wherein the forming the third build-up part includes alternately laminating the third conductor layers and the third insulating layers.

15. The method for manufacturing a wiring substrate according to claim 2, wherein the forming the second build-up part includes forming a second resist layer having a second resist pattern and forming a second conductor pattern according to the second resist pattern for each of the second conductor layers, and the forming of the second resist layer having the second resist pattern includes exposing the second resist layer using a photomask.

16. The method for manufacturing a wiring substrate according to claim 2, wherein the at least one product area in each of the support substrates has a rectangular shape with each side in a range of 80 mm to 240 mm.

17. The method for manufacturing a wiring substrate according to claim 2, wherein the first surface of each of the support substrates has a flatness of ±2.5 μm or less.

18. The method for manufacturing a wiring substrate according to claim 17, wherein each of the support substrates is one of a glass substrate, a silicon substrate, a metal substrate, and a ceramic substrate.

19. The method for manufacturing a wiring substrate according to claim 2, wherein the forming the first build-up part includes forming the first conductor layers each having the conductor pattern such that wirings in the conductor pattern have a minimum width of 2 μm or less and a minimum inter-wiring distance of 2 μm or less.

20. The method for manufacturing a wiring substrate according to claim 2, wherein the first build-up part is formed such that each of the first conductor layers has a thickness of 7 μm or less, and the second build-up part is formed such that each of the second conductor layers has a thickness of 10 μm or more.
